(19) United States
(12) Patent Application Publication
(10) Pub. No.: US 2025/0223719 A1
(43) Pub. Date: Jul. 10, 2025

(54) CRYSTAL PREPARATION DEVICES AND CRYSTAL PREPARATION METHODS

(71) Applicant: MEISHAN BOYA ADVANCED MATERIALS CO., LTD., Meishan (CN)

(72) Inventors: Yu WANG, Meishan (CN); Peng GU, Meishan (CN); Zhenxing LIANG, Meishan (CN); Min LI, Meishan (CN)

(73) Assignee: MEISHAN BOYA ADVANCED MATERIALS CO., LTD., Meishan (CN)

(21) Appl. No.: 19/026,562

(22) Filed: Jan. 17, 2025

Related U.S. Application Data
(63) Continuation of application No. PCT/CN2022/106463, filed on Jul. 19, 2022.

(51) Int. Cl. C30B 15/30; C30B 15/02; C30B 15/20; C30B 29/36

(52) U.S. Cl. CPC C30B 15/30; C30B 15/02; C30B 15/20; C30B 29/36

(57) ABSTRACT

The embodiments of the present disclosure provide a crystal preparation device and a crystal preparation method. The crystal preparation device comprises a growth chamber configured to place a raw material; a heating component configured to heat the growth chamber; a pulling component configured for pulling growth; and a guide component in a transmission connection with the pulling component. The crystal preparation method comprises providing a raw material in the growth chamber; descending the pulling component bonded with a seed crystal to a vicinity of the raw material, the pulling component being in transmission connection with the guide component and at least a portion of the pulling component being located in the guide component; heating the growth chamber to form a raw material melt; and growing a crystal based on the seed crystal and the raw material melt through a transmission movement of the pulling component and the guide component.

### CROSS-REFERENCES TO RELATED APPLICATIONS

This application is a continuation of International Application No. PCT/CN2022/106463, filed on Jul. 19, 2022, the entire contents of which are incorporated herein by reference.

### TECHNICAL FIELD

The present disclosure relates to the technical field of crystal preparation, and in particular to a crystal preparation device and method based on a liquid phase technique.

### BACKGROUND

When crystals are prepared based on a liquid phase technique (e.g., top-seeded solution growth (TSSG)), some components (e.g., silicon) in a raw material are easily volatile at a high temperature, which easily leads to segregation of melt component, spontaneous nucleation on a seed crystal surface or a melt surface, etc. In addition, a temperature field changes due to a change in the melt surface during a pulling growth process, which affects the normal growth of the crystal. Therefore, it is desirable to provide an improved crystal preparation device and method to ensure the normal growth of a crystal.

### SUMMARY

One of the embodiments of the present disclosure provides a crystal preparation device. The crystal preparation device may comprise a growth chamber configured to place a raw material; a heating component configured to heat the growth chamber; a pulling component configured for pulling growth; and a guide component in a transmission connection with the pulling component.

In some embodiments, the guide component may include a barrel, and at least a portion of the pulling component may be located in the barrel.

In some embodiments, a diameter of the barrel may gradually increase from a bottom to a top of the barrel.

In some embodiments, a thickness of the barrel may be in a range of 1 mm-3 mm.

In some embodiments, an angle between a sidewall of the barrel and a horizontal plane may be in a range of 100°-140°.

In some embodiments, a sidewall of the barrel may be provided with one or more through holes.

In some embodiments, a diameter of each of the one or more through holes may be in a range of 0.5 mm-2 mm.

In some embodiments, a distance between each of the one or more through holes and a bottom portion of the barrel may be in a range of 3 mm-10 mm.

In some embodiments, a density of the one or more through holes may be in a range of 3/cm²-10/cm².

In some embodiments, a graphite paper may be provided at a bottom portion of the cylinder.

In some embodiments, a thickness of the graphite paper may be in a range of 100 μm-300 μm.

In some embodiments, the guide component may further include a transmission mechanism. The transmission mechanism may be in the transmission connection with the barrel to realize an upward and downward movement of the barrel.

In some embodiments, the transmission mechanism may include: connection rings located at a top sidewall of the barrel and the pulling component; connection members connected with the connection rings; rotation shafts located on a support frame at an upper portion of the growth chamber and connected with the connection members; and stoppers located on the connection members and cooperate with the rotation shafts to stop movements of the connection members.

In some embodiments, the crystal preparation device may further comprise: a support component configured to support the growth chamber; a driving component configured to drive the support component to perform an upward and downward movement; and a temperature measurement component configured to measure a temperature in the growth chamber.

One of the embodiments of the present disclosure further provides a temperature measurement device. The temperature measurement device may comprise a support component configured to support a growth chamber; a driving component configured to drive the support component to perform an upward and downward movement; and a temperature measurement component configured to measure a temperature in the growth chamber.

One of the embodiments of the present disclosure further provides a crystal preparation method. The crystal preparation method may comprise: providing a raw material in a growth chamber; descending a pulling component bonded with a seed crystal to the vicinity of the raw material, the pulling component being in a transmission connection with a guide component and at least a portion of the pulling component being located in the guide component; heating the growth chamber to form a raw material melt; and growing a crystal based on the seed crystal and the raw material melt through a transmission movement of the pulling component and the guide component.

In some embodiments, the guide component may include a barrel. At least a portion of the pulling component bonded with the seed crystal may be located in the barrel. A sidewall of the barrel may be provided with one or more through holes.

In some embodiments, during the raw material melt to form the raw material melt, the seed crystal may be located below the one or more through holes.

In some embodiments, during crystal growing based on the seed crystal and the raw material melt, at least a portion of the one or more through holes may be located in the raw material melt.

In some embodiments, the growing a crystal based on the seed crystal and the raw material melt through a transmission movement of the pulling component and the guide component may include: controlling, by controlling a pulling speed of the pulling component, an immersion speed and/or an immersion amount of the barrel into the raw material melt to maintain a constant liquid level of the raw material melt.

### BRIEF DESCRIPTION OF THE DRAWINGS

The present disclosure will be further illustrated by way of exemplary embodiments, which will be described in detail by means of the accompanying drawings. These embodiments are not limiting, and in these embodiments, the same numbering indicates the same structure, wherein:

FIG. 1 is a schematic structural diagram illustrating an exemplary crystal preparation device according to some embodiments of the present disclosure;

FIG. 2 is a schematic structural diagram illustrating an exemplary pulling component and an exemplary guide component according to some embodiments of the present disclosure;

FIG. 3 is a schematic diagram illustrating an exemplary temperature rising and material melting stage according to some embodiments of the present disclosure;

FIG. 4 is a schematic diagram illustrating an exemplary seeding stage according to some embodiments of the present disclosure;

FIG. 5 is a schematic diagram illustrating an exemplary pulling growth stage according to some embodiments of the present disclosure;

FIG. 6 is a schematic diagram illustrating an exemplary pulling growth stage according to some embodiments of the present disclosure;

FIG. 7 is a schematic diagram illustrating an exemplary end of crystal growth according to some embodiments of the present disclosure;

FIG. 8 is a schematic structural diagram illustrating an exemplary temperature measurement device according to some embodiments of the present disclosure; and

FIG. 9 is a flowchart illustrating an exemplary crystal preparation method according to some embodiments of the present disclosure.

In the figures, 100 represents a crystal preparation device, 110 represents a growth chamber, 120 represents a heating component, 130 represents a pulling component, 131 represents a seed crystal holder, 132 represents a pulling rod, 140 represents a guide component, 141 represents a barrel, 1411 represents through holes, 1411′ represents lowermost through holes, 1412 represents graphite paper, 142 represents a transmission mechanism, 1421 represents connection rings, 1422 represents connection members, 1423 represents rotation shafts, 1424 represents stoppers, 1425 represents a support frame, 150 represents a heat preservation component, 160 represents a furnace body, 170 represents an observation component, 180 represents a sensing component, 800 represents a temperature measurement device, 810 represents a support component, 820 represents a driving component, 821 represents a fixing part, 822 represents a screw rod, 823 represents a power part, and 830 represents a temperature measurement component.

### DETAILED DESCRIPTION

In order to more clearly illustrate the technical solutions of the embodiments of the present disclosure, the accompanying drawings required to be used in the description of the embodiments are briefly described below. Obviously, the accompanying drawings in the following description are only some examples or embodiments of the present disclosure, and it is possible for a person of ordinary skill in the art to apply the present disclosure to other similar scenarios in accordance with these drawings without creative labor. Unless obviously obtained from the context or the context illustrates otherwise, the same numeral in the drawings refers to the same structure or operation.

It should be understood that the terms “system,” “device,” “unit” and/or “module” used herein are a way to distinguish between different components, elements, parts, sections, or assemblies at different levels. However, the terms may be replaced by other expressions if other words accomplish the same purpose.

As shown in the present disclosure and in the claims, unless the context clearly suggests an exception, the words “one,” “a,” “an,” “one kind,” and/or “the” do not refer specifically to the singular, but may also include the plural. Generally, the terms “including” and “comprising” suggest only the inclusion of clearly identified steps and elements, however, the steps and elements that do not constitute an exclusive list, and the method or apparatus may also include other steps or elements.

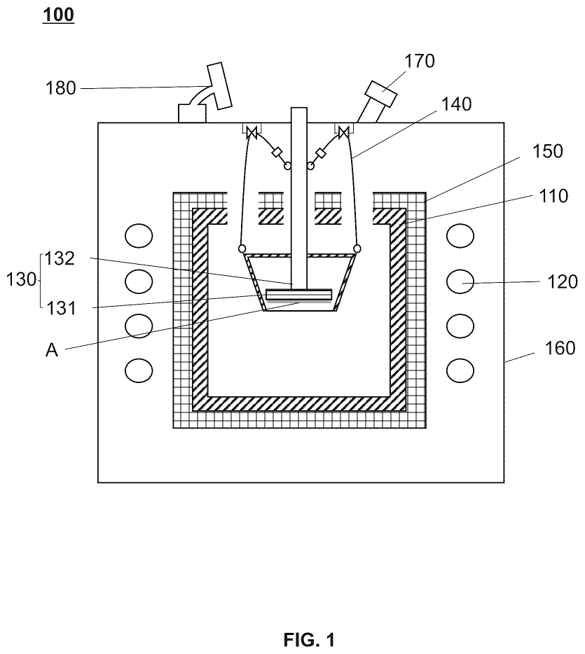

FIG. 1 is a schematic structural diagram illustrating an exemplary crystal preparation device according to some embodiments of the present disclosure.

In some embodiments, a crystal preparation device 100 may be configured to prepare a crystal (e.g., silicon carbide) based on a liquid phase technique. The crystal preparation device 100 involved in the embodiments of the present disclosure will be illustrated in detail below with reference to the accompanying drawings by taking the preparation of a silicon carbide crystal as an example. It should be noted that the following embodiments are only used to explain the present disclosure and do not constitute a limitation on the present disclosure.

As shown in FIG. 1, the crystal preparation device 100 may include a growth chamber 110, a heating component 120, a pulling component 130, and a guide component 140.

The growth chamber 110 may be used as a place for crystal preparation. The heating component 120 may be configured to heat the growth chamber 110 to provide the heat (e.g., a temperature, a temperature field, etc.) required for crystal preparation.

In some embodiments, a material of the growth chamber 110 may be determined based on a type of a crystal to be prepared. For example, when a silicon carbide crystal is prepared, the material of the growth chamber 110 may include graphite. The graphite may be used as a carbon source to provide the carbon required for preparing the silicon carbide crystal. In some embodiments, the material of the growth chamber 110 may further include molybdenum, tungsten, tantalum, etc. In some embodiments, a raw material (e.g., silicon powder, and carbon powder) required for preparing the crystal may be placed in the growth chamber 110. In some embodiments, the growth chamber 110 may be a place where the raw material is melted to form a melt. For example, under a high temperature provided by the heating component 120, the silicon powder melts into a melt (liquid), and the carbon provided by the growth chamber 110 dissolves in the silicon solution to form a solution of carbon in silicon, which is used as a liquid raw material for preparing the silicon carbide crystal by the liquid phase method. In some embodiments, in order to increase the solubility of carbon in silicon, a flux (e.g., aluminum, a silicon-chromium alloy, a Li—Si alloy, a Ti—Si alloy, a Fe—Si alloy, an Sc—Si alloy, a Co—Si alloy, etc.) may be added to the raw material.

In some embodiments, the heating component 120 may include an induction heating component, a resistance heating component, etc. In some embodiments, the heating component 120 may be disposed around the periphery of the growth chamber 110. In some embodiments, as shown in FIG. 1, the heating component 120 may include an induction coil. In some embodiments, the induction coil may be disposed around the periphery of the growth chamber 110.

In some embodiments, the pulling component 130 may move upward and downward and/or rotate to implement pulling growth. In some embodiments, as shown in FIG. 1, the pulling component 130 may include a seed crystal receptacle 131 and a pulling rod 132. In some embodiments, a seed crystal (e.g., as shown in “A” in FIG. 1) may be bonded to a lower surface of the seed crystal holder 131. In some embodiments, the pulling rod 132 may be connected with the seed crystal holder 131 to drive the seed crystal holder 131 to move upward and downward and/or rotate.

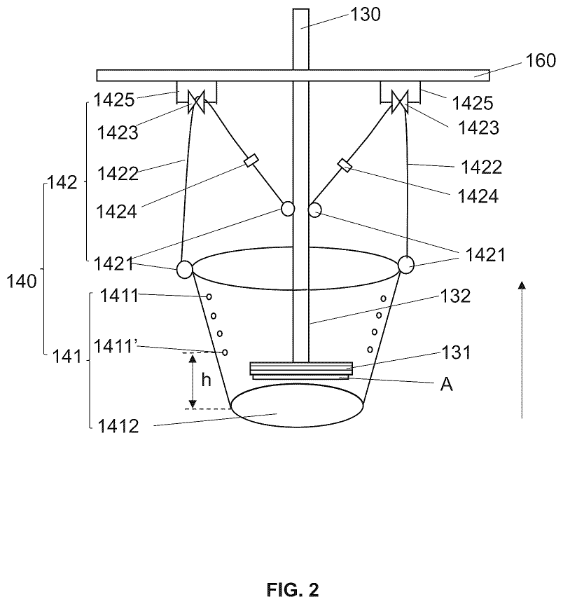

In some embodiments, the guide component 140 may be in a transmission connection with the pulling component 130. In some embodiments, the guide component 140 and the pulling component 130 may perform a transmission movement. More descriptions regarding the pulling component 130 and the guide component 140 may be found elsewhere in the present disclosure (e.g., FIG. 2 and the related descriptions thereof), which are not repeated here.

In some embodiments, the crystal preparation device 100 may further include a power component (not shown in the figure) configured to drive the pulling component 130 to rotate and/or move upward and downward, so as to drive the seed crystal holder 131 or a seed crystal A to rotate and/or move upward and downward to grow the crystal. In some embodiments, the power component may include but is not limited to an electric drive device, a hydraulic drive device, a pneumatic drive device, or the like, or any combination thereof, which is not limited in the present disclosure.

In some embodiments, the crystal preparation device 100 may further include a heat preservation component 150 for heat preservation of the growth chamber 110. In some embodiments, the heat preservation component 150 may be disposed around the periphery of the growth chamber 110. In some embodiments, the material of the heat preservation component 150 may include quartz (silicon oxide), corundum (aluminum oxide), zirconium oxide, carbon fibers, ceramic, or the like, or other high-temperature resistant materials (e.g., boride, carbide, nitride, silicide, phosphide and sulfide of a rare earth metal, etc.).

In some embodiments, the crystal preparation device 100 may further include a furnace body 160. In some embodiments, the furnace body 160 may be disposed outside the growth chamber 110, the heating component 120, and the heat preservation component 150.

In some embodiments, as shown in FIG. 1, an upper portion of each of the growth chamber 110, the heat preservation component 150, and the furnace body 160 is provided with a through hole to allow the pulling component 130 and/or the guide pulling component 140 to pass through for rotation and/or upward and downward movement.

In some embodiments, the crystal preparation device 100 may further include an observation component 170 (e.g., an observation window). The crystal growth in the growth chamber 110 may be observed in real time through the observation component 170. In some embodiments, as shown in FIG. 1, the observation component 170 may be located on an upper wall of the furnace body 160.

In some embodiments, the crystal preparation device 100 may further include a sensing component 180. In some embodiments, the sensing component 180 may be configured to monitor information related to the crystal growth (e.g., temperature information, a pulling speed and/or a rotation speed of the pulling component 130, liquid level position information, and a crystal appearance (e.g., a size)). In some embodiments, the sensing component 180 may be located on the upper wall of the furnace body 160. In some embodiments, the sensing component 180 may include a temperature sensing element, a speed sensing element, a liquid level sensor (e.g., a radar probe, and a radar level gauge), image acquisition equipment, etc.

In some embodiments, the temperature sensing part may be configured to measure the temperature information in the growth chamber 110. In some embodiments, the temperature sensing part may include an infrared thermometer, a photoelectric pyrometer, a fiber optic radiation thermometer, a colorimetric thermometer, an ultrasonic thermometer, or the like, or any combination thereof.

In some embodiments, the speed sensing part may be configured to measure the pulling speed (e.g., an ascending speed, and a descending speed) and/or the rotation speed of the pulling component 130.

In some embodiments, the liquid level sensor may be configured to measure liquid level position information and/or liquid level height information of the melt in the growth chamber 110.

In some embodiments, the image acquisition equipment may include infrared imaging equipment, X-ray imaging equipment, ultrasonic imaging equipment, or the like, or any combination thereof.

In some embodiments, the crystal preparation device 100 may further include a processing component (not shown in the figure). In some embodiments, the processing component may receive the information related to the crystal growth sent by the sensing component 180, and control other components (e.g., the heating component 120, the pulling component 130, the guide component 140, and the power component) of the crystal preparation device 100 based on the information related to the crystal growth to ensure the normal growth of the crystal. For example, the processing component may control the pulling speed and/or the rotation speed of the pulling component 130 based on the liquid level position information and/or the liquid level height information to control an immersion speed and/or an immersion amount of at least a portion of parts (e.g., a barrel 141 shown in FIG. 2) of the guide component 140 immersed in the raw material melt to maintain a constant liquid level of the raw material melt. As another example, the processing component may control the power component based on the pulling speed and/or the rotation speed of the pulling component 130 to make the pulling speed and/or the rotation speed of the pulling component 130 meet the requirements of each stage of the crystal growth. As another example, the processing component may control the heating power of the heating component 120 and/or the position of the heating component 120 based on the temperature information in the growth chamber 110 to maintain a stable temperature field.

In some embodiments, the processing component may include a central processing unit (CPU), an application specific integrated circuit (ASIC), an application specific instruction set processor (ASIP), a graphics processing unit (GPU), a physical processing unit (PPU), a digital signal processor (DSP), a field programmable gate array (FPGA), a programmable logic device (PLD), a controller, a microcontroller unit, a reduced instruction set computer (RISC), a microprocessor, or the like, or any combination thereof.

In some embodiments, the crystal preparation device 100 may further include a display component (not shown in the figure). In some embodiments, the display component may display the information related to the crystal growth (e.g., the temperature information, the pulling speed and/or the rotation speed of the pulling component 130, the liquid level position information, and the crystal appearance), etc., in real time.

In some embodiments, the display component may include a liquid crystal display, a plasma display, a light-emitting diode display, or the like, or any combination thereof.

In some embodiments, the crystal preparation device 100 may further include a storage component (not shown in the figure). The storage component may store data, instructions, and/or any other information. In some embodiments, the storage component may store data and/or information involved in a crystal preparation process. For example, the storage component may store the temperature information and the liquid level position information involved in the crystal preparation process, and/or data and/or instructions for performing the exemplary crystal preparation method described in the embodiments of the present disclosure.

In some embodiments, the storage component may include a USB flash disk, a mobile hard disk, an optical disk, a memory card, or the like, or any combination thereof.

It should be noted that the above description of the crystal preparation device 100 is only for illustration and description, and does not limit the scope of application of the present disclosure. For those skilled in the art, various modifications and changes can be made to the crystal preparation device 100 under the guidance of the present disclosure. However, these modifications and changes are still within the scope of the present disclosure.

FIG. 2 is a schematic structural diagram illustrating an exemplary pulling component and an exemplary guide component according to some embodiments of the present disclosure.

In some embodiments, as shown in FIG. 2, the guide component 140 may include a barrel 141 and a transmission mechanism 142. In some embodiments, the transmission mechanism 142 may be in a transmission connection with the barrel 141 to achieve an upward and downward movement of the barrel 141. In some embodiments, the transmission mechanism 142 may also be in the transmission connection with the pulling component 130 (e.g., the pulling rod 132). In some embodiments, the pulling component 130 may be in the transmission connection with the transmission mechanism 142 to further drive the barrel 141 to perform the upward and downward movement. In some embodiments, during the crystal growth process, the pulling component 130, the barrel 141, and the transmission mechanism 142 may be in the transmission connection with each other and/or transmission movement with each other to control growth parameters (e.g., a temperature field, and a liquid level position and/or height) during the crystal growth process.

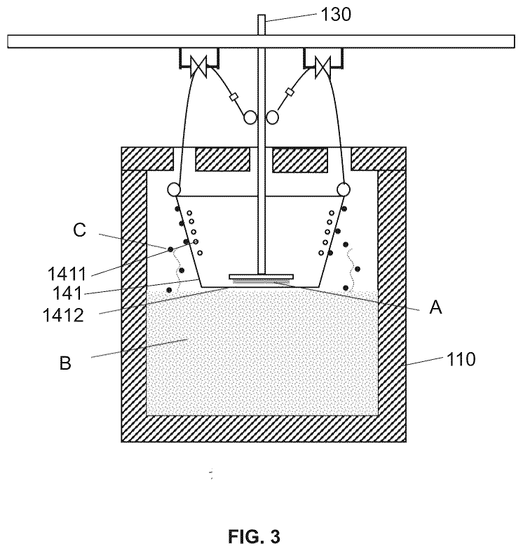

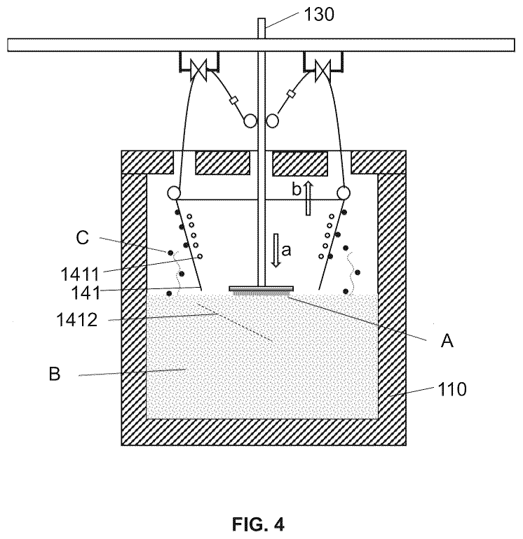

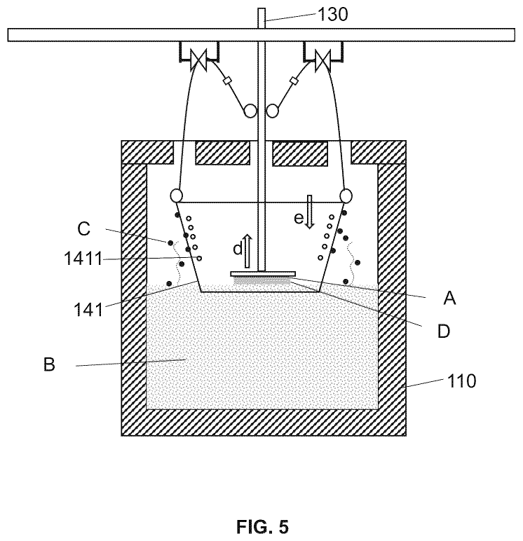

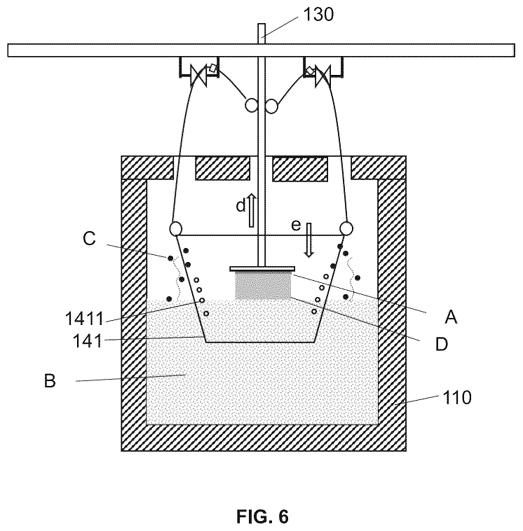

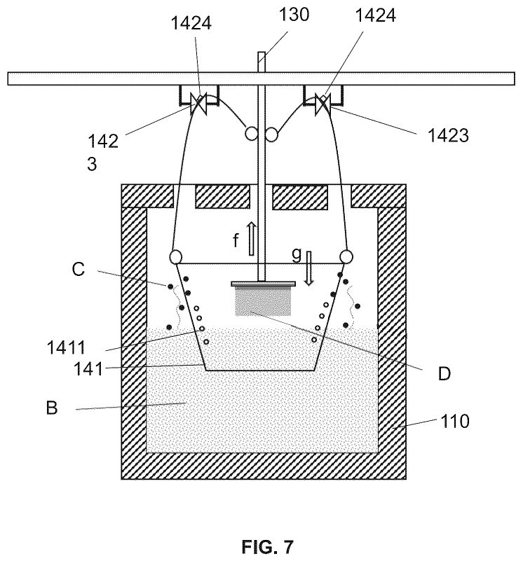

For example, FIGS. 3-7 are schematic diagrams illustrating an exemplary temperature rising and material melting stage, an exemplary seeding stage, an exemplary pulling growth stage, and an exemplary end of crystal growth according to some embodiments of the present disclosure. As shown in FIG. 3, before the temperature rising and material melting stage (i.e., a stage when a raw material is melted into a melt), the pulling component 130 and the guide component 140 may be in transmission movement with each other, such that in the temperature rising and material melting stage, at least a portion of the pulling rod 132 is located in the barrel 141, and the seed crystal holder 131 is located in the barrel 141 and above the raw material. As shown in FIG. 4, in the seeding stage, the pulling component 130 may move downward (as shown by an arrow a in FIG. 4), and the barrel 141 may be driven to move upward (as shown by an arrow b in FIG. 4) through the transmission mechanism 142. As shown in FIG. 5 and FIG. 6, in the pulling growth stage, the pulling component 130 may move upward (as shown by an arrow d in FIG. 5 and FIG. 6), and the barrel 141 may be driven to move downward (as shown by an arrow e in FIG. 5 and FIG. 6) through the transmission mechanism 142. As shown in FIG. 7, at the end of the crystal growth, the pulling component 130 may move upward (as shown by an arrow f in FIG. 7), and the barrel 141 may be driven to move downward (as shown by an arrow g in FIG. 7) through the transmission mechanism 142.

In general, during the growth of silicon carbide crystals, since the silicon component is volatile, the volatilized silicon vapor moves and adheres to the heat preservation component, destroying the heat preservation performance of the heat preservation component. Accordingly, in the embodiments of the present disclosure, by introducing the barrel 141 (especially a trapezoidal barrel with a wide upper portion and a narrow lower portion), the volatilized silicon vapor can be attached to a sidewall of the barrel 141, which prevents the silicon vapor from moving to the heat preservation component 150, thereby ensuring the heat preservation performance and service life of the heat preservation component 150.

In addition, the silicon vapor is also easy to adhere to the surface of the seed crystal, resulting in spontaneous nucleation. The barrel 141 in the embodiments of present disclosure can protect and/or keep heat preservation of the seed crystal and/or the growing crystal. Since the crystal grows inside the barrel 141, a temperature field distribution around the growing crystal can be improved, the thermal stress inside the crystal can be reduced, and the pulled crystal can be prevented from cracking due to extreme cold.

Furthermore, during the crystal growth process, as the pulling growth of the crystal, the melt liquid level gradually decreases, resulting in a significant fluctuation in the temperature field near the melt liquid level and impurity inclusions in the crystal. The barrel 141 (and the transmission mechanism 142) in the embodiments of the present disclosure allows the barrel 141 to gradually immerse into the melt as the crystal grow to dynamically adjust the liquid level position and/or height and maintain the liquid level basically stable. In addition, the silicon attached to the sidewall of the barrel 141 can compensate the melt for silicon, thereby reducing the segregation of melt components caused by silicon volatilization. Furthermore, the barrel 141 can act as a heat reflection screen, which can reduce the supersaturation of the melt liquid level and avoid spontaneous nucleation on the melt surface to form a floating crystal.

In some embodiments, a material of the barrel 141 may include graphite, which can provide carbon required for preparing the silicon carbide crystal.

In some embodiments, the diameter of the barrel 141 may gradually increase from the bottom to the top of the barrel 141 (as shown by an arrow in FIG. 2). In some embodiments, the barrel 141 may be a trapezoidal barrel.

In some embodiments, the thickness of the barrel 141 and an angle between the sidewall of the barrel 141 and a horizontal plane may affect the melt liquid level, a temperature field, etc., during the crystal growth process, which in turn affects the temperature field and the crystal quality of the crystal growth. For example, if the thickness of the barrel 141 is too small or the angle between the sidewall of the barrel 141 and the horizontal plane is too large, as the pulling component 130 pulls up during the crystal growth process, a portion of the barrel 141 immersed into the raw material melt is small, and a portion of the melt consumed by the crystal growth is not effectively supplemented, and the temperature field and the stable height of the liquid level required for the crystal growth are not effectively guaranteed. As another example, if the thickness of the barrel 141 is too large or the angle between the sidewall of the barrel 141 and the horizontal plane is too small, the portion of the barrel 141 immersed into the raw material melt during the crystal growth process is too large, which is also unable to effectively guarantee the stable height of the liquid level.

In some embodiments, during the pulling growth stage, the angle between the sidewall of the barrel 141 and the horizontal plane also affects a distance between the seed crystal or the growing crystal with the sidewall of the barrel 141, which affects the radial growth rate of the crystal, and further affects crystal expansion growth and a shoulder angle of the crystal.

Therefore, in some embodiments, the thickness of the barrel 141 and the angle between the sidewall of the barrel 141 and the horizontal plane need to meet preset requirements.

In some embodiments, the thickness of the barrel 141 may be in a range of 1 mm-3 mm. In some embodiments, the thickness of the barrel 141 may be in a range of 1.2 mm-2.8 mm. In some embodiments, the thickness of the barrel 141 may be in a range of 1.4 mm-2.6 mm. In some embodiments, the thickness of the barrel 141 may be in a range of 1.6 mm-2.4 mm. In some embodiments, the thickness of the barrel 141 may be in a range of 1.8 mm-2.2 mm. In some embodiments, the thickness of the barrel 141 may be in a range of 1.9 mm-2 mm.

In some embodiments, the angle between the sidewall of the barrel 141 and the horizontal plane may be in a range of 100°-140°. In some embodiments, the angle between the sidewall of the barrel 141 and the horizontal plane may be in a range of 105°-135°. In some embodiments, the angle between the sidewall of the barrel 141 and the horizontal plane may be in a range of 110-130°. In some embodiments, the angle between the sidewall of the barrel 141 and the horizontal plane may be in a range of 115°-125°. In some embodiments, the angle between the sidewall of the barrel 141 and the horizontal plane may be in a range of 118°-120°.

In some embodiments, the sidewall of the barrel 141 may be provided with one or more through holes 1411. During the crystal growth process, the one or more through holes 1411 may serve as one or more transmission channels between a melt inside the barrel 141 and a melt outside the barrel 141.

In some embodiments, the shape of each of the one or more through holes 1411 may include a regular or irregular shape such as a circle, an ellipse, a polygon, a star, etc. In some embodiments, the shapes of the one or more through holes 1411 may be the same or different.

In some embodiments, the diameter of each of the one or more through holes 1411 and a density of the one or more through holes 1411 may affect a transmission process and thus affect the quality of the growing crystal. For example, if the diameter of each of the one or more through holes 1411 or the density of the through holes 1411 is too small, the transmission efficiency between the melt inside the barrel 141 and the melt outside the barrel 141 is low. As another example, if the diameter of each of the one or more through holes 1411 is too large, the floating crystals cannot be effectively prevented from entering the inside of the barrel 141, which affects the crystal quality. As another example, if the density of the one or more through holes 1411 is too large, the volatilized silicon vapor moves to the inside of the barrel 141 through the one or more through holes 1411 located above the melt, and deposits on the surface of the crystal, which affects the crystal quality. Accordingly, in some embodiments, the diameters and the density of the one or more through holes 1411 need to meet the preset requirements.

In some embodiments, the diameter of each of the one or more through holes 1411 may be in a range of 0.5 mm-2 mm. In some embodiments, the diameter of each of the one or more through holes 1411 may be in a range of 0.7 mm-1.8 mm. In some embodiments, the diameter of each of the one or more through holes 1411 may be in a range of 0.9 mm-1.6 mm. In some embodiments, the diameter of each of the one or more through holes 1411 may be in a range of 1.1 mm-1.4 mm. In some embodiments, the diameter of each of the one or more through holes 1411 may be in a range of 1.2 mm-1.3 mm.

In some embodiments, the density of the one or more through holes 1411 may be expressed as a count of one or more through holes 1411 per unit area. In some embodiments, the density of the one or more through holes 1411 may be in a range of 3/cm²-10/cm². In some embodiments, the density of the one or more through holes 1411 may be in a range of 4/cm²-9/cm². In some embodiments, the density of the one or more through holes 1411 may be in a range of 5/cm²-8/cm². In some embodiments, the density of the one or more through holes 1411 may be in a range of 6/cm²-7/cm². In some embodiments, a distance between the one or more through holes 1411 and the bottom portion of the barrel 141 may affect the crystal growth process and/or the crystal quality. For example, if the distance between the one or more through holes 1411 and the bottom portion of the barrel 141 is too small, at least part of the one or more through holes 1411 are located below or close to the seed crystal in the temperature rising and material melting stage (e.g., as shown in FIG. 3), and the volatilized silicon vapor enters the barrel 141 through the part of the through holes 1411 and deposits on the surface of the seed crystal, which affects the crystal quality. As another example, if the distance between the one or more through holes 1411 and the bottom portion of the barrel 141 is too large, the one or more through holes 1411 cannot be effectively immersed into the melt during the crystal growth process, and thus cannot achieve effective melt transmission, which further affects the crystal quality. Accordingly, in some embodiments, the distance between the one or more through holes 1411 and the bottom portion of the barrel 141 needs to meet the preset requirements. In the embodiments of the present disclosure, the distance between the one or more through holes 1411 and the bottom portion of the barrel 141 may be understood as a distance (as shown in h in FIG. 2) between lowermost through holes 1411′ and the bottom portion of the barrel 141.

In some embodiments, the distance between the one or more through holes 1411 and the bottom portion of the barrel 141 may be in a range of 3 mm-10 mm. In some embodiments, the distance between the one or more through holes 1411 and the bottom portion of the barrel 141 may be in a range of 3.5 mm-9.5 mm. In some embodiments, the distance between the one or more through holes 1411 and the bottom portion of the barrel 141 may be in a range of 4 mm-9 mm. In some embodiments, the distance between the one or more through holes 1411 and the bottom portion of the barrel 141 may be in a range of 4.5 mm-8.5 mm. In some embodiments, the distance between the one or more through holes 1411 and the bottom of portion the barrel 141 may be in a range of 5 mm-8 mm. In some embodiments, the distance between the one or more through holes 1411 and the bottom portion of the barrel 141 may be in a range of 5.5 mm-7.5 mm. In some embodiments, the distance between the one or more through holes 1411 and the bottom portion of the barrel 141 may be in a range of 6 mm-7 mm.

In some embodiments, the bottom portion of the barrel 141 may be provided with a graphite paper 1412. In the temperature rising and material melting stage (e.g., as shown in FIG. 3), the graphite paper 1412 may prevent the volatilized silicon vapor (e.g., as shown in “C” in FIG. 3) from adhering to the surface of the seed crystal (e.g., as shown in “A” in FIG. 3), which further ensures the quality of the crystal growth. In the seeding stage (e.g. as shown in FIG. 4), by descending of the pulling component 130 (as shown by an arrow a in FIG. 4) and ascending of the guide component 140 (e.g., the barrel 141) (as shown by an arrow b in FIG. 4), the seed crystal can be gradually close to the graphite paper 1412 to lightly touch the graphite paper 1412 and make the graphite paper 1412 fall into the melt. The graphite paper 1412 can be dissolved in the melt to provide the carbon required for preparing the silicon carbide crystal without any additional pollution.

In some embodiments, the shape of the graphite paper 1412 may be adapted to the bottom shape of the barrel 141. For example, if the bottom shape of the barrel 141 is a circle, the graphite paper 1412 may be a circle. In some embodiments, the diameter of the graphite paper 1412 may be slightly greater than a bottom diameter of the barrel 141. Accordingly, in the temperature rising and material melting stage, the graphite paper 1412 may be located at the bottom portion of the barrel 141 and does not fall off automatically; in the seeding stage, the graphite paper 1412 may be lightly touched to fall into the melt.

In some embodiments, the diameter of the graphite paper 1412 may be slightly greater than the bottom diameter of the barrel 141 by about 0.5 mm-1 mm. In some embodiments, the diameter of the graphite paper 1412 may be greater than the bottom diameter of the barrel 141 by about 0.6 mm-0.9 mm. In some embodiments, the diameter of the graphite paper 1412 may be greater than the bottom diameter of barrel 141 by about 0.7 mm-0.8 mm.

In some embodiments, the thickness of the graphite paper 1412 may affect the crystal growth process and further affect the crystal quality. For example, if the thickness of the graphite paper 1412 is too small, the volatilized silicon vapor may cause the graphite paper 1412 to move upward or drift in the temperature rising and material melting stage, causing the volatilized silicon vapor to move to the upward side of the graphite paper 1412 through a gap between the graphite paper 1412 and the inner wall of the barrel 141 and adhere to the surface of the seed crystal, which affects the crystal quality. As another example, if the thickness of the graphite paper 1412 is too large, the time for the graphite paper 1412 to melt in the melt is relatively long, which further affects the stability of the melt liquid level and affects the crystal growth process. Accordingly, in some embodiments, the thickness of the graphite paper 1412 needs to meet the preset requirements.

In some embodiments, the thickness of the graphite paper 1412 may be in a range of 100 μm-300 μm. In some embodiments, the thickness of the graphite paper 1412 may be in a range of 120 μm-280 μm. In some embodiments, the thickness of the graphite paper 1412 may be in a range of 140 μm-260 μm. In some embodiments, the thickness of the graphite paper 1412 may be in a range of 160 μm-240 μm. In some embodiments, the thickness of the graphite paper 1412 may be in a range of 180 μm-220 μm. In some embodiments, the thickness of the graphite paper 1412 may be in a range of 200 μm-210 μm.

In some embodiments, a top cover may be provided on the top portion of the barrel 141 to reduce a temperature gradient above the crystal, maintain a stable temperature field, and improve the crystal quality. In some embodiments, the top cover may include a through hole such that the pulling component 130 can pass through the through hole for a pulling movement. In some embodiments, the shape of the top cover may be adapted to the top shape of the barrel 141. For example, the top shape of the barrel 141 may be a circle, and the top cover may be a circle. In some embodiments, the material of the top cover may include but is not limited to graphite.

In some embodiments, as shown in FIG. 2, the transmission mechanism 142 may include one or more connection rings 1421, one or more connection members 1422, one or more rotation shafts 1423, and one or more stoppers 1424.

In some embodiments, a portion of the one or more connection rings 1421 may be located on a top sidewall of the barrel 141. In some embodiments, a portion of the one or more connection rings 1421 may be located on the pulling component 130 (e.g., the pulling rod 132).

In some embodiments, the count of the one or more connection rings 1421 may be 3, 4, 5, etc. In some embodiments, multiple connection rings 1421 located on the top sidewall of the barrel 141 may be evenly distributed to maintain the barrel 141 as stable as possible when the barrel 141 moves upward and downward, and further ensure the stability of the melt liquid level.

In some embodiments, each of the one or more connection members 1422 may be configured to connect a connection ring 1421 located on the top sidewall of the barrel 141 and a connection ring 1421 located on the pulling component 130 to connect the barrel 141 and the pulling component 130 (e.g., the pulling rod 132).

In some embodiments, the one or more rotation shafts 1423 may be located on a support frame at an upper portion of the growth chamber 110 or on the furnace body 160. For example, the one or more rotation shafts 1423 may be fixed to a support frame 1425 disposed on the furnace body 160. In some embodiments, the one or more rotation shafts 1423 may include but are not limited to fixed pulleys.

In some embodiments, one of the one or more connection members 1422 may pass through one of the one or more rotation shafts 1423 to connect one of the one or more connection rings 1421 located on the top sidewall of the barrel 141 and one of the one or more connection rings 1421 located on the pulling component 130, such that a movement direction of the pulling component 130 (e.g., the pulling rod 132) is opposite to a movement direction of the barrel 141. For example, in the seeding stage, when the pulling component 130 moves downward (as shown by an arrow a in FIG. 4), the barrel 141 moves upward (as shown by an arrow b in FIG. 4) to make the seed crystal A be gradually close to the graphite paper 1412. As another example, in the pulling growth stage, when the pulling component 130 (e.g., the pulling rod 132) moves upward (as shown by an arrow d in FIG. 5 and FIG. 6), the barrel 141 moves downward (as shown by an arrow e in FIG. 5 and FIG. 6) to immerse into the melt to supplement the melt consumed by the crystal growth, so as to further maintain the stability of the height of the melt liquid level.

In some embodiments, the one or more stoppers 1424 may be located on the connection members 1422. In some embodiments, the one or more stoppers 1422 may be located on the one or more connection members 1422 close to the one or more connection rings 1421 connected to the pulling component 130. In some embodiments, the one or more stoppers 1422 being located on the one or more connection members 1422 close to the one or more connection rings 1421 connected to the pulling component 130 means that one of the one or more stoppers 1422 may be located on one of the one or more connection members 1422 within a preset distance from one of the one or more connection rings 1421 connected to the pulling component 130. In some embodiments, the preset distance may include but is not limited to 10 cm, 8 cm, 6 cm, 4 cm, 2 cm, 1 cm, etc. In some embodiments, the one or more stoppers 1424 may cooperate with the one or more rotation shafts 1423 to block the movement of the one or more connection members 1422. For example, as shown in FIG. 7, after the end of the crystal growth, when the pulling component 130 continues to move upward (as shown by an arrow f in FIG. 7), the one or more stoppers 1424 may be stuck at the one or more rotation shafts 1423 to prevent the barrel 141 from continuing to descend and melting in the melt.

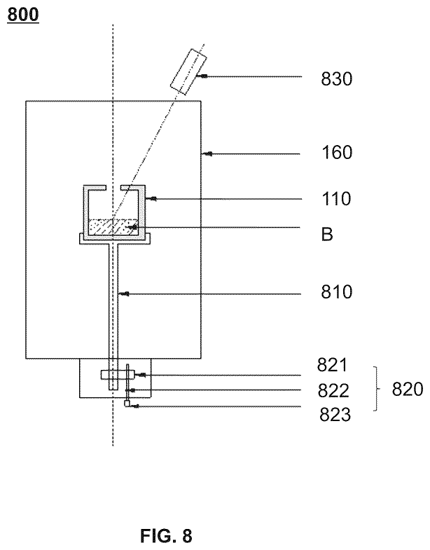

In some embodiments, the crystal preparation device 100 may further include a support component, a driving component, and a temperature measurement component (collectively referred to as a “temperature measurement device”). More descriptions may be found elsewhere in the present disclosure (e.g., FIG. 8 and the related descriptions thereof), which are not repeated here.

FIG. 8 is a schematic structural diagram illustrating an exemplary temperature measurement device according to some embodiments of the present disclosure. In some embodiments, a temperature measure device 800 may be configured to measure a temperature related to the growth chamber 110. In some embodiments, the temperature measurement device 800 may be configured to determine a position of a high temperature line. In some embodiments, the temperature measurement device 800 may move the growth chamber 110 to make a liquid level of the melt located at the position of the high temperature line, so as to improve the crystal quality. The temperature measurement device 800 involved in the embodiments of the present disclosure will be described in detail with reference to the accompanying drawings by taking the preparation of silicon carbide crystals as an example. It should be noted that the following embodiments are only used to explain the present disclosure and do not constitute a limitation of the present disclosure.

As shown in FIG. 8, the temperature measurement device 800 may include a support component 810, a driving component 820, and a temperature measurement component 830.

In some embodiments, the support component 810 may be disposed below growth chamber 110 to support growth chamber 110. In some embodiments, the support component 810 may be fixedly connected with the growth chamber 110. For example, an end of the support component 810 may be connected to an outer bottom portion of the growth chamber 110 through a threaded chuck. In some embodiments, at least a portion of the support component 810 may be located in the furnace body 160.

In some embodiments, the driving component 820 may be configured to drive the support component 810 to move upward and downward, to further drive the growth chamber 110 to move upward and downward.

In some embodiments, the driving component 820 may include a fixing part 821, a screw rod 822, and a power part 823.

In some embodiments, the fixing part 821 may be configured to fix the support component 810 and connect the support component 810 and the screw rod 822. For example, the fixing part 821 may be welded to the support component 810. In some embodiments, the fixing part 821 may be in the transmission connection (e.g., threaded connection) with the screw rod 822. In some embodiments, the fixing component 821 may be provided with internal threads, and the screw rod 822 may be provided with external threads, and the connection between the fixing component 821 and the screw rod 822 may be achieved by the cooperation of the internal threads and the external threads.

In some embodiments, the power part 823 may be configured to provide power for the screw rod 822. For example, the power part 823 may drive the screw rod 822 to rotate, and the rotation of the screw rod 822 may drive the fixing part 821 and the support component 810 to move upward and downward to further drive the growth chamber to move upward and downward.

In some embodiments, the temperature measurement component 830 may be configured to measure a temperature (e.g., a temperature at the melt liquid level) in the growth chamber 110. In the embodiments of the present disclosure, the temperature measurement component and the temperature sensing part of the crystal preparation device 100 described in FIG. 1 may be the same or similar components or parts.

In some embodiments, the temperature measurement device 800 may further include a processing component. The processing component of the temperature measurement device 800 and the processing component of the crystal preparation device 100 may be the same processing component or independent processing components.

In some embodiments, the processing component may receive temperature information in the growth chamber 110 sent by the temperature measurement component 830, and determine the position of the high temperature line (i.e., a position with the highest temperature in the growth chamber 110 or a horizontal position) based on the temperature information. For example, if a temperature of a specific position above the liquid level of the melt (also referred to as the melt liquid level) measured by the temperature measurement component 830 is higher than the temperature of any other position (e.g., any position other than the specific position), the processing component may determine that the specific position above the liquid level of the melt is the position of the high temperature line. As another example, if the temperature of a specific position below the melt liquid level measured by the temperature measurement component 830 is higher than the temperature of any other position (e.g., any position other than the specific position), the processing component may determine that the specific position below the melt liquid level is the position of the high temperature line. As another example, if the temperature of the melt liquid level measured by the temperature measurement component is higher than the temperature of other positions in the growth chamber (e.g., any position above or below the melt liquid level), the processing component may determine that the melt liquid level is located at the position of the high temperature line.

In some embodiments, the processing component may compare the temperature of the melt liquid level with the temperature of other positions (i.e., positions above the melt liquid level or positions below the melt liquid level) when the growth chamber is located at different positions.

In some embodiments, the processing component may control the driving component 820 to drive the support component 810 to move upward and downward based on the position of the high temperature line, such that the growth chamber 110 moves to make the melt liquid level be located at the position of the high temperature line, thereby growing a high-quality crystal (e.g., a crystal without defects such as inclusions). For example, if the position of the high temperature line is located at a specific position above the melt liquid level, the processing component may control the driving component 820 to drive the support component 810 to move upward, such that the growth chamber 110 moves upward until the melt liquid level is located at the specific position. As another example, if the position of the high temperature line is located at a specific position below the melt liquid level, the processing component may control the driving component 820 to drive the support component 810 to move downward, such that the growth chamber 110 moves downward until the melt liquid level is located at the specific position.

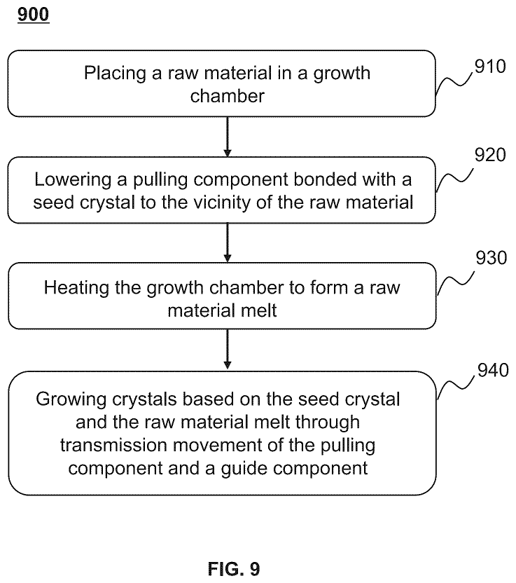

FIG. 9 is a flowchart illustrating an exemplary crystal preparation method according to some embodiments of the present disclosure. A process 900 may be performed by one or more components of a crystal preparation device (e.g., the crystal preparation device 100). In some embodiments, the process 900 may be automatically performed by a control system. For example, the process 900 may be implemented by a control instruction, and the control system may control each component to complete each operation of the process 900 based on the control instruction. In some embodiments, the process 900 may be semi-automatically performed. For example, one or more operations of the process 900 may be manually performed by an operator. In some embodiments, when the process 900 is performed, one or more additional operations not described may be added, and/or one or more operations discussed herein may be deleted. In addition, the order of the operations shown in FIG. 9 is not limited. As shown in FIG. 9, the process 900 may include the following operations.

In 910, a raw material may be placed in a growth chamber (e.g., the growth chamber 110).

In some embodiments, the raw material refers to a raw material required for crystal growing. For example, when a silicon carbide crystal is prepared, the raw material may include silicon (e.g., silicon powder, silicon wafers, silicon blocks), and the growth chamber (e.g., a graphite chamber) may serve as a carbon source. As another example, when a silicon carbide crystal is prepared, the raw material may include silicon and carbon (e.g., carbon powder, carbon blocks, carbon particles), i.e., an additional carbon source may be provided to increase the service life of the growth chamber. In some embodiments, the raw material may also include a flux for increasing the solubility of carbon in silicon. In some embodiments, the flux may include but is not limited to aluminum, a silicon-chromium alloy, a Li—Si alloy, a Ti—Si alloy, a Fe—Si alloy, a Sc—Si alloy, and a Co—Si alloy. More descriptions regarding the growth chamber may be found elsewhere in the present disclosure (e.g., FIG. 1 and the related descriptions thereof), which are not repeated here.

In 920, a pulling component (e.g., the pulling component 130) bonded with a seed crystal may be lowered to the vicinity of the raw material.

In some embodiments, the pulling component bonded with the seed crystal may be driven downward to be lowered to the vicinity of the raw material by a power component. In some embodiments, the vicinity of the raw material refers to a preset distance from an upper surface of the raw material. In some embodiments, the preset distance may include but is not limited to 10 cm, 8 cm, 6 cm, 4 cm, 2 cm, 1 cm, 0.5 cm, 0.3 cm, 0.1 cm, etc.

In some embodiments, the puling component may be in the transmission connection with the guide component (e.g., the guide component 140), and at least a portion of the puling component may be located in the guide component (e.g., in the barrel 141).

More descriptions regarding the puling component, the guide component, the power component, etc., may be found elsewhere in the present disclosure (e.g., FIG. 1, FIG. 2 and the related descriptions thereof), which are not repeated here.

In 930, the growth chamber may be heated to form a melt of the raw material (also referred to as a raw material melt).

In some embodiments, the growth chamber may be heated by a heating component (e.g., the heating component 130) to melt the raw material to form the raw material melt. For example, when growing silicon carbide crystals, the raw material is melted to form a solution of carbon in silicon to serve as a liquid raw material for crystal growth.

In some embodiments, as shown in FIG. 3, during the process of melting the raw material to form the raw material melt (i.e., a temperature rising and material melting stage), the seed crystal may be located below the one or more through holes 1411 of a sidewall of the barrel 141. Accordingly, even if the silicon vapor (e.g., as shown in “C” in FIG. 3) enters the barrel 141 through the through holes 1411, since the seed crystal is located below the one or more through holes 1411, the silicon vapor does not deposit on the surface of the seed crystal (e.g., a seeding surface), which can protect the seeding surface of the seed crystal and avoid spontaneous nucleation of the seed crystal in the subsequent seeding stage.

In some embodiments, in the temperature rising and material melting stage, a distance between the bottom portion of the barrel 141 or the graphite paper at the bottom portion of the barrel 141 and a melt liquid level may be in a first preset range. In some embodiments, the graphite paper at the bottom portion of the barrel 141 may contact the seeding surface of the seed crystal, but there is no interaction force between the graphite paper at the bottom portion of the barrel 141 and the seeding surface of the seed crystal. In some embodiments, the distance between the melt liquid level and one of the bottom portion of the barrel 141 or the graphite paper at the bottom portion of the barrel 141 may affect the crystal quality. For example, if the distance between the melt liquid level and one of the bottom portion of the barrel 141 or the graphite paper at the bottom portion of the barrel 141 is too small, the graphite paper 1412 may be eroded in the temperature rising and material melting stage, which results in the inability to protect the seeding surface of the seed crystal, affects the quality of the seed crystal, and thus affects the crystal quality. As another example, if the distance between the melt liquid level and one of the bottom portion of the barrel 141 or the graphite paper at the bottom portion of the barrel 141 is too large, the upward movement of the pulling component cannot make the barrel 141 contact with the melt in the subsequent pulling growth stage, which results in the barrel 141 being unable to prevent the floating crystals from entering the crystal growth interface, and affects the crystal quality. Accordingly, in some embodiments, the distance between the melt liquid level and one of the bottom portion of the barrel 141 or the graphite paper at the bottom portion of the barrel 141 needs to be within a first preset range.

In some embodiments, the first preset range may be in a range of 5 mm-10 mm. In some embodiments, the first preset range may be in a range of 6 mm-9 mm. In some embodiments, the first preset range may be in a range of 7 mm-8 mm.

In some embodiments, the melt liquid level may be adjusted to be located at a position of a high temperature line through a temperature measurement device (e.g., the temperature measurement device 800) to grow a high-quality crystal (e.g., a crystal without defects such as inclusions).

In some embodiments, the position of the growth chamber may be adjusted through the temperature measurement device (e.g., the temperature measurement device 800), and the temperature of the melt liquid level in the growth chamber when the growth chamber is located at different positions may be compared to make the growth chamber located at a position to cause the highest temperature of the melt liquid level (i.e., the melt liquid level is located at the position of the high temperature line). For example, the temperature of the melt liquid level (which may be expressed as “T0”) at a current position (which may be expressed as “S0”) of the growth chamber may be measured by the temperature measurement component. With the current position SO of the growth chamber as a starting point, the processing component may control the driving component to drive the support component to move upward, such that the growth chamber moves upward by a first preset distance to a first position, and the temperature of the melt liquid level (which may be expressed as “T1”) of the growth chamber at the first position may be measured by the temperature measurement component. With the current position SO of the growth chamber as the starting point, the processing component may control the driving component to drive the support component to move downward, such that the growth chamber moves downward by the first preset distance to a second position, and the temperature of the melt liquid level (which may be expressed as “T2”) of the growth chamber at the second position may be measured by the temperature measurement component. T0, T1, and T2 may be compared, and if a temperature difference between T0 and T1 or a temperature difference between T0 and T2 is greater than a preset temperature difference range, a position of the growth chamber where the melt liquid level of the growth chamber has the highest temperature (the highest temperature may be represented as “Tmax1”) among T0, T1, and T2 may be selected as an initial position of a second adjustment of the growth chamber (the initial position of the second adjustment may be represented as “S1”). In some embodiments, the preset temperature difference range may not be greater than 0.5° C., 1° C., or 2° C., etc.

With the initial position S1 of the second adjustment as the starting point, the processing component may control the driving component to drive the support component to move upward or downward respectively, such that the growth chamber moves upward or downward by a second preset distance to a third position or a fourth position, and the temperature of the melt liquid level T3 and T4 of the growth chamber at the third position and the fourth position may be measured by the temperature measurement component, respectively. Tmax1, T3 and T4 may be compared, and if Tmax1 is greater than T3, Tmax1 is greater than T4, and a temperature difference between Tmax1 and T3 and a temperature difference between Tmax1 and T4 are not greater than the preset temperature difference range, the position of the melt liquid level where Tmax1 is located is the position of the high temperature line. If the temperature difference between Tmax1 and T3 or the temperature difference between Tmax1 and T4 is greater than the preset temperature difference range, a position of the growth chamber where the melt liquid level of the growth chamber has the highest temperature (the highest temperature may be expressed as “Tmax2”) among Tmax1, T3 and T4 may be selected as an initial position of a third adjustment of the growth chamber (the initial position of the third adjustment may be expressed as “S2”). By repeating this process, it is determined that the position of the melt liquid level with the highest temperature is the position of the high temperature line, and at this time the melt liquid level is located at the position of the high temperature line.

In some embodiments, the first preset distance may be not less than the second preset distance. In some embodiments, the first preset distance may be greater than the second preset distance to improve the determination efficiency of the high temperature line.

In some embodiments, the position of the high temperature line may also be determined by the temperature measurement device (e.g., the temperature measurement device 800), and the growth chamber may be further moved to make the melt liquid level located at the position of the high temperature line. In some embodiments, temperature information in the growth chamber may be measured by the temperature measurement component, and the measured temperature information may be sent to the processing component. In some embodiments, the processing component may determine the position of the high temperature line based on the temperature information, and drive the support component to move through the driving component to further drive the growth chamber to move such that the melt liquid level is located at the position of the high temperature line. For example, if the temperature of a specific position above the melt liquid level measured by the temperature measurement component is higher than the temperature of any other position (e.g., any position other than the specific position), the processing component may control the driving component to drive the support component to move upward such that the growth chamber moves upward until the melt liquid level is located at the specific position. As another example, if the temperature of a specific position below the melt liquid level measured by the temperature measurement component is higher than the temperature of any other position (e.g., any position other than the specific position), the processing component may control the driving component to drive the support component to move downward such that the growth chamber moves downward until the melt liquid level is located at the specific position. As another example, if the temperature of the melt liquid level measured by the temperature measurement component is higher than the temperature of other positions in the growth chamber (e.g., any position above or below the melt liquid level), it is determined that the melt liquid level is located at the position of the high temperature line.

More descriptions regarding the temperature measurement device may be found elsewhere in the present disclosure (e.g., FIG. 8 and the related descriptions thereof), which are not repeated here.

In 940, a crystal may grow based on the seed crystal and the raw material melt through transmission movement of the pulling component and a guide component.

In some embodiments, as shown in FIG. 4, in the seeding stage, the power component may drive the pulling component 130 to move downward (as shown by an arrow a in FIG. 4), such that the guide component 140 (e.g., the barrel 141) moves upward (as shown by an arrow b in FIG. 4), and the seed crystal is gradually close to the graphite paper disposed at the bottom portion of the barrel 141. With continued movement, the seed crystal may lightly touch the graphite paper to make the graphite paper fall into the melt.

In some embodiments, as shown in FIG. 5 and FIG. 6, in the pulling growth stage, the pulling component 130 may be driven to rotate and move upward (as shown by an arrow d in FIG. 5 and FIG. 6) by the power component, such that the guide component 140 (e.g., the barrel 141) moves downward (as shown by an arrow e in FIG. 5 and FIG. 6), and the melt can enter the bottom portion of the barrel 141 and condense and crystallize at the seed crystal to grow the crystal.

In some embodiments, as shown in FIG. 6, during the process (i.e., the pulling growth stage) of growing the crystal based on the seed crystal and the raw material melt, at least part of one or more through holes 1411 on the sidewall of the barrel 141 may be located in the melt. The one or more through holes 1411 may serve as transmission channels between the melt inside the barrel 141 and the melt outside the barrel 141.

As described above, as the pulling growth proceeds, part of the melt is consumed and the melt liquid level gradually decreases, which results in a significant fluctuation in a temperature field near the liquid level, and causes impurity inclusions in the crystal. Accordingly, in some embodiments, the sensing component may monitor information related to the crystal growth and send the information related to the crystal growth to the processing component. The processing component may control, based on the information related to the crystal growth, a pulling speed and/or a rotation speed of the pulling component to control an immersion speed and/or an immersion amount of the barrel into the raw material melt, thereby maintaining a constant liquid level the raw material melt. For example, the liquid level sensor may measure liquid level position information and/or liquid level height information of the melt in the growth chamber during the crystal growth, and send the liquid level position information and/or the liquid level height information to the processing component. When a part of the melt is consumed to cause the melt liquid level to be lower than an initial melt liquid level, the processing component may determine a consumption speed and/or consumption amount of the melt based on the liquid level position information and/or the liquid level height information, and further calculate the pulling speed of the pulling component based on a thickness of the barrel and an angle between the sidewall of the barrel and a horizontal plane, such that the immersion speed of the barrel into the melt is equal to the consumption speed of the melt and/or the immersion amount of the barrel into the melt is equal to the consumption amount of the melt, thereby maintaining the constant liquid level of the raw material melt, maintaining the stable temperature field, and ensuring the normal growth of the crystals.

It should be noted that the above description of the process 900 is only for example and explanation, and does not limit the scope of application of the present disclosure. For those skilled in the art, various modifications and changes may be made to the process 900 under the guidance of the present disclosure. However, these modifications and changes are still within the scope of the present disclosure.

### Emobodiment 1

Raw material silicon and a flux for SiC crystal growth are placed in a growth chamber, and a crystal preparation device is assembled. A pulling component bonded with a seed crystal is descended to the vicinity of the raw material by a power component. The growth chamber is heated by a heating component to melt the raw material to form a melt. During a temperature rising and material melting stage, a distance between a melt liquid level and one of a bottom of a barrel and graphite paper at the bottom portion of the barrel and is in a range of 5 mm-10 mm. After material melting is completed, a distance between a seeding surface of the seed crystal and the melt liquid level is in a range of 6 mm-12 mm. The pulling component is descended by the power component, and the seed crystal touches the graphite paper to make the graphite paper fall into the melt. After a preset time period (e.g., 0.5 h), the seed crystal contacts the melt for seeding.

After the seed crystal contacts the melt for 10 min-30 min, the pulling component rotates and moves upward through the power component to grow the crystal. During the upward movement of the pulling component, the barrel descends to partially immerse and dissolve in the melt. In a pulling growth stage, a sensing component monitors information related to the crystal growth and sends the information related to the crystal growth to the processing component. The processing component controls a pulling speed and/or a rotation speed of the pulling component based on the information related to the crystal growth to control an immersion speed and/or an immersion amount of the barrel into the raw material melt to maintain a constant liquid level of the raw material melt.

When stoppers on the connection members move to graphite rotation shafts, the stoppers are stuck and the barrel stops descending, and the pulling growth stage ends. The pulling component moves upward through the power component to separate the crystal from the melt so as to obtain SiC crystal without inclusions.

The beneficial effects that may be brought about by the embodiments of the present disclosure include but are not limited to the following content. (1) The crystal growth is carried out in the barrel of the guide component through the transmission movement of the pulling component and the guide component, the temperature of the temperature field is improved, and the melt liquid level is kept stable during the growth process through the transmission movement, thereby improving the crystal quality. (2) The diameter of the barrel gradually increases from the bottom to the top of the barrel. During the crystal growth, the volatilized silicon vapor moves upward to the sidewall of the barrel, which correspondingly prevents the volatilized silicon vapor from moving to the heat preservation component, thereby ensuring the heat preservation performance and the service life of the heat preservation component. Furthermore, in the pulling growth stage, as the pulling component pulls upward, the barrel descends to partially immerse into the melt, and the silicon attached to the sidewall of the barrel can compensate the melt for silicon, thereby reducing the segregation of melt components. Meanwhile, the barrel can act as a heat reflection screen, which can reduce the supersaturation of the melt liquid level and avoid spontaneous nucleation on the melt liquid level to form floating crystals. (3) During the pulling growth stage, as the pulling component moves upward, part of the barrel is immersed into the melt. One or more through holes on the sidewall of the barrel are immersed into the melt, and the through holes can serve as the transmission channels between the melt inside the barrel and the melt outside the barrel. The through holes can also prevent a floating crystal outside the barrel from entering the inside of the barrel, thereby maintaining the stable crystal growth. (4) The graphite paper is provided at the bottom portion of the barrel. During the temperature rising and material melting stage, the graphite paper can prevent the volatilized silicon vapor from adhering to the surface of the seed crystal, thereby further ensuring the quality of the crystal growth. In the seeding stage, the seed crystal can lightly touch the graphite paper to make the graphite paper fall into and dissolve in the melt, thereby providing the raw material carbon required for preparing the silicon carbide crystal. (5) The processing component can control the pulling speed and/or the rotation speed of the pulling component based on information related to the crystal growth (e.g., the liquid level position information) to control the immersion speed and/or the immersion amount of the barrel into the raw material melt, thereby maintaining the constant liquid level of the raw material melt, maintaining the stable temperature field, ensuring the normal crystal growth, and improving the crystal quality. It should be noted that different embodiments may produce different beneficial effects. In different embodiments, the beneficial effects may be any one or a combination of the above, or any other beneficial effects that may be obtained.

Having thus described the basic concepts, it may be rather apparent to those skilled in the art after reading this detailed disclosure that the foregoing detailed disclosure is intended to be presented by way of example only and is not limiting. Various alterations, improvements, and modifications may occur and are intended to those skilled in the art, though not expressly stated herein. These alterations, improvements, and modifications are intended to be suggested by this disclosure and are within the spirit and scope of the exemplary embodiments of this disclosure.

Moreover, certain terminology has been used to describe embodiments of the present disclosure. For example, the terms “one embodiment,” “an embodiment,” and “some embodiments” mean that a particular feature, structure, or feature described in connection with the embodiment is included in at least one embodiment of the present disclosure. Therefore, it is emphasized and should be appreciated that two or more references to “an embodiment” or “one embodiment” or “an alternative embodiment” in various portions of this specification are not necessarily all referring to the same embodiment. Furthermore, the particular features, structures, or features may be combined as suitable in one or more embodiments of the present disclosure.

Similarly, it should be appreciated that in the foregoing description of embodiments of the present disclosure, various features are sometimes grouped together in a single embodiment, figure, or description thereof for the purpose of streamlining the disclosure aiding in the understanding of one or more of the various embodiments. This method of disclosure, however, is not to be interpreted as reflecting an intention that the claimed subject matter requires more features than are expressly recited in each claim. Rather, claimed subject matter may lie in less than all features of a single foregoing disclosed embodiment.

In some embodiments, numbers describing the number of ingredients and attributes are used. It should be understood that such numbers used for the description of the embodiments use the modifier “about,” “approximately,” or “substantially” in some examples. Unless otherwise stated, “about,” “approximately,” or “substantially” indicates that the number is allowed to vary by ±20%. Correspondingly, in some embodiments, the numerical parameters used in the description and claims are approximate values, and the approximate values may be changed according to the required features of individual embodiments. In some embodiments, the numerical parameters should consider the prescribed effective digits and adopt the method of general digit retention. Although the numerical ranges and parameters used to confirm the breadth of the range in some embodiments of the present disclosure are approximate values, in specific embodiments, settings of such numerical values are as accurate as possible within a feasible range.

For each patent, patent application, patent application publication, or other materials cited in the present disclosure, such as articles, books, specifications, publications, documents, or the like, the entire contents of which are hereby incorporated into the present disclosure as a reference. The application history documents that are inconsistent or conflict with the content of the present disclosure are excluded, and the documents that restrict the broadest scope of the claims of the present disclosure (currently or later attached to the present disclosure) are also excluded. It should be noted that if there is any inconsistency or conflict between the description, definition, and/or use of terms in the auxiliary materials of the present disclosure and the content of the present disclosure, the description, definition, and/or use of terms in the present disclosure is subject to the present disclosure.

Finally, it should be understood that the embodiments described in the present disclosure are only used to illustrate the principles of the embodiments of the present disclosure. Other variations may also fall within the scope of the present disclosure. Therefore, as an example and not a limitation, alternative configurations of the embodiments of the present disclosure may be regarded as consistent with the teaching of the present disclosure. Accordingly, the embodiments of the present disclosure are not limited to the embodiments introduced and described in the present disclosure explicitly.

1. A crystal preparation device, comprising:
a growth chamber configured to place a raw material;
a heating component configured to heat the growth chamber;
a pulling component configured for pulling growth; and
a guide component in a transmission connection with the pulling component.

2. The crystal preparation apparatus of claim 1, wherein the guide component includes a barrel, and at least a portion of the pulling component is located in the barrel.

3. The crystal preparation device of claim 2, wherein a diameter of the barrel gradually increases from a bottom to a top of the barrel.

4. The crystal preparation device of claim 2, wherein a thickness of the barrel is in a range of 1 mm-3 mm.

5. The crystal preparation device of claim 2, wherein an angle between a sidewall of the barrel and a horizontal plane is in a range of 100°-140°.

6. The crystal preparation device of claim 2, wherein a sidewall of the barrel is provided with one or more through holes.

7. The crystal preparation device of claim 6, wherein a diameter of each of the one or more through holes is in a range of 0.5 mm-2 mm.

8. The crystal preparation device of claim 6, wherein a distance between each of the one or more through holes and a bottom portion of the barrel is in a range of 3 mm-10 mm.

9. The crystal preparation device of claim 6, wherein a density of the one or more through holes is in a range of 3/cm²-10/cm².

10. The crystal preparation device of claim 2, wherein a graphite paper is provided at a bottom portion of the barrel.

11. The crystal preparation device of claim 10, wherein a thickness of the graphite paper is in a range of 100 μm-300 μm.

12. The crystal preparation device of claim 2, wherein the guide component further includes a transmission mechanism, and the transmission mechanism is in a transmission connection with the barrel to realize an upward and downward movement of the barrel.

13. The crystal preparation device of claim 12, wherein the transmission mechanism includes:
connection rings located at a top sidewall of the barrel and the pulling component;
connection members connected with the connection rings;
rotation shafts located on a support frame at an upper portion of the growth chamber and connected with the connection members; and
stoppers located on the connection members and cooperate with the rotation shafts to stop movements of the connection members.

14. The crystal preparation device of claim 1, further comprising:
a support component configured to support the growth chamber;
a driving component configured to drive the support component to perform an upward and downward movement; and
a temperature measurement component configured to measure a temperature in the growth chamber.

15. (canceled)

16. A crystal preparation method, comprising:
providing a raw material in a growth chamber;
descending a pulling component bonded with a seed crystal to a vicinity of the raw material, wherein:
the pulling component is in a transmission connection with a guide component and at least a portion of the pulling component is located in the guide component;
heating the growth chamber to form a raw material melt; and
growing a crystal based on the seed crystal and the raw material melt through a transmission movement of the pulling component and the guide component.

17. The crystal preparation method of claim 16, wherein the guide component includes a barrel, at least a portion of the pulling component bonded with the seed crystal is located in the barrel, and a sidewall of the barrel is provided with one or more through holes.

18. The crystal preparation method of claim 17, wherein:
during the raw material melt to form the raw material melt, the seed crystal is located below the one or more through holes.

19. The crystal preparation method of claim 17, wherein
during crystal growing based on the seed crystal and the raw material melt, at least a portion of the one or more through holes are located in the raw material melt.

20. The crystal preparation method of claim 17, wherein the growing a crystal based on the seed crystal and the raw material melt through a transmission movement of the pulling component and the guide component includes:
controlling, by controlling a pulling speed of the pulling component, an immersion speed and/or an immersion amount of the barrel into the raw material melt to maintain a constant liquid level of the raw material melt.

21. The crystal preparation method of claim 16, wherein
a graphite paper is provided at a bottom portion of the barrel;
growing a crystal based on the seed crystal and the raw material melt through a transmission movement of the pulling component and the guide component includes:
controlling a downward movement of the pulling component and an upward movement of the barrel to make the seed crystal close to the graphite paper and the graphite paper fall into and dissolve in the raw material melt.
